(19) United States
(12) Patent Application Publication
(10) Pub. No.: US 2006/0110930 A1
(43) Pub. Date: May 25, 2006

(54) Direct liquid injection system and method for forming multi-component dielectric films

(76) Inventor: Yoshihide Senzaki, Austin, TX (US)

Correspondence Address: DORSEY & WHITNEY LLP, 555 CALIFORNIA STREET, SUITE 1000, SUITE 1000, SAN FRANCISCO, CA, 94104, US

(21) Appl. No.: 11/205,431

(22) Filed: Aug. 16, 2005

Related U.S. Application Data
(60) Provisional application No. 60/602,189, filed on Aug. 16, 2004.

(51) Int. Cl. H01L 21/31

(52) U.S. Cl. 438/758

(57) ABSTRACT

The present invention provides methods and systems for atomic layer deposition (ALD). In some embodiments a system is provided comprising: at least one direct liquid injection system configured to inject one or more deposition precursors into one or more vaporization chambers, at least one bubble system configured to vaporize one or more deposition precursors; and a process chamber coupled to said direct liquid injection system and said bubblers system, said process chamber being configured to receive the deposition precursors from said direct liquid injection and bubbler systems and being adapted to carry out an ALD process. In an alternative embodiment, the system is comprised of two separate bubbler systems. In another alternative embodiment, the system is comprised of two separate direct liquid injection systems.

### CROSS REFERENCE TO RELATED APPLICATIONS

This application claims the benefit of, and priority to, U.S. Provisional Patent application Ser. No. 60/602,189 filed Aug. 16, 2004, the disclosure of which is incorporated by reference herein in its entirety.

### FIELD OF THE INVENTION

In general, the present invention relates to systems and methods for forming thin films in semiconductor applications. More specifically, the present invention relates to systems and methods for fabricating multi-component thin films on a substrate using mixed vaporized precursors.

### BACKGROUND OF THE INVENTION

Concurrent with the increase in sophistication and drive towards miniaturization of microelectronics, the number of transistors per integrated circuit has exponentially grown and promises to grow to meet the demands for faster, smaller and more powerful electronic systems. However, as traditional silicon-based transistor geometries reach a critical point where the silicon dioxide gate dielectric becomes just a few atomic layers thick, tunneling of electrons will become more prevalent leading to current leakage and increase in power dissipation. Accordingly, an alternative dielectric possessing a higher permittivity or dielectric constant than silicon dioxide and capable of preventing current tunneling or leakage would be highly desirable. Among the most promising dielectric candidates to replace silicon dioxide are metal oxides including hafnium oxide, zirconium oxide and tantalum oxide.

Unfortunately, these materials are chemically and thermally unstable on silicon, unlike silicon dioxide, forming defects and charge traps at the interface between the metal dielectric and the silicon substrate. The charge traps and defects interact with the voltage applied at the gate and perturb the performance and reliability of the transistor. To limit the formation of interfacial charge traps and defects, an interfacial layer of silicon dioxide is deposited between the dielectric and the silicon substrate. The silicon dioxide interface buffers the silicon substrate from the dielectric, but the silicon dioxide interface may not be compatible with the surface properties of the dielectric. Accordingly, an interface that can ameliorate the surface properties and chemistries of the dielectric and silicon substrate, while minimizing the equivalent physical oxide thickness, is needed to fabricate ultra-thin high k dielectrics.

Prior art deposition techniques for fabricating films such as chemical vapor deposition (CVD) are increasingly unable to meet the requirements of advanced thin films. While CVD processes can be tailored to provide conformal films with improved step coverage, CVD processes often require high processing temperatures. For instance, one of the obstacles of making high-k gate dielectrics is the formation of an interfacial silicon oxide layer during CVD processes. Gas phase reaction in CVD leads to particle generation. Another obstacle is the limitation of prior art CVD processes in depositing ultra thin films for high k gate dielectrics on a silicon substrate.

An alternative to traditional CVD processes to deposit very thin films is Atomic layer deposition (ALD). ALD has several advantages over traditional CVD. ALD can be performed at comparatively low temperatures that are compatible with the industry's trend toward lower temperatures, and can produce conformal thin film layers. The existing method for depositing multi-component films, such as a HfₓSi_{y}O₂(x+y=1) film, using an ALD processes is to deposit laminate films of HfO₂ and SiO₂ film using a sequential vapor deposition method. That is, the precursor chemicals are not mixed, and instead a Hf containing precursor and a Si containing precursor are pulsed independently and sequentially into the chamber to form laminate layers of HfO₂ and SiO₂, respectively. In fact, any mixing of precursors is prohibited, and the chamber is purged of one precursor before the second precursor is pulsed. Once the laminate films are formed to a desired thickness, the film is annealed in an attempt to arrive at a more continuous composition throughout the film. This approach of building up layers of different laminate films leads to many electron traps in the film due to the multiple interfaces which requires a high temperature thermal anneal to fix the traps. The addition of the high temperature thermal annealing step increases cost and time for manufacturing semiconductors, and moreover can result in the undesirable out migration of elements from previously formed layers on the wafer. In addition, it is difficult to control the stoichiometric composition of multi-component films in the laminate method. The dielectric constant (k), crystallization temperature and refractive index of HfSiOₓ, films cannot be easily controlled by the traditional one chemical sequential precursor pulse methods (such as the laminate method). Furthermore, the cycle times needed to form a film of desired thickness using the conventional sequential pulse and purge of one chemical precursor at a time are impractical and require too much time for future IC manufacturing.

Attempts to fabricate multi-component films using mixed precursors have been limited to the traditional CVD methods. For example, U.S. Pat. Nos. 6,537,613 and 6,238,734 both to Senzaki et al. (the '613 and '734 patents) generally disclose systems and methods for generating a compositional gradient comprising a metal and metalloid compound. There are several drawbacks associated with the method described in the '613 and '734 patents. One of the major drawbacks of the prior art is the limitation in film composition control. In addition, it is a liquid mixture that is injected into the chamber. As such, if the liquid mixture is not thoroughly mixed, a film having an uneven composition and gradient will form on the substrate. In addition, even if appropriate volumes of samples are provided, there is no guarantee that the mixture will vaporize uniformly since each precursor has a unique boiling point, vapor pressure and volatility. Furthermore, if the discrepancy in boiling points between the precursors is substantial, one precursor may decompose at the boiling point of the second forming particulates or contaminants. Generally, either the precursors have not been adequately mixed, resulting in a non-uniform film composition, or mixing of the two vapors causes pre-reaction in the gas phase, resulting in the formation of particles or contaminants that are deposited on the wafer.

Accordingly, there is a need for further developments in methods of fabricating multi-component films, particularly when using direct liquid injection to deliver precursors to a chamber to form multi-component films using an ALD process.

### BRIEF SUMMARY OF THE INVENTION

In general, the inventor has discovered a method that provides for mixing vaporized precursors such that a mixture of vaporized precursors are present together in a chamber during a single deposition or pulse step in an atomic layer deposition (ALD) process to form a multi-component film. The vaporized precursors are each comprised of at least one different chemical component, and such different components will form a monolayer to produce a multi-component film. This application is related to U.S. patent application Ser. No. 10/869,779 filed on Jun. 15, 2004 and U.S. patent application Ser. No. 10/829,781 filed on Apr. 21, 2004 which are herby incorporated by reference in their entirety. Such a method is a departure from the prior art, where the vaporized precursors are pulsed separately into the chamber in the ALD process to form separate monolayers containing only one of the components.

One aspect of the present invention provides systems and methods for fabricating multi-component dielectric films by mixing vaporized precursors together and then injecting or co-injecting the vaporized precursors such that a mixture of precursors are present in the ALD chamber. As used herein the term “multi-component” film means that the film contains two or more metal or metalloid elements. A variety of multi-component films may be formed by the present invention, including but not limited to: metal, metal alloy, mixed metal oxides, silicates, nitrides, oxynitrides, and mixtures thereof.

In one embodiment of the present invention, a method of forming a thin film on a surface of a substrate by atomic layer deposition is provided, characterized in that: two or more vaporized precursors, each of the precursors containing at least one different chemical component (typically a metal or metalloid element), are conveyed into a process chamber together to form a monolayer on the surface of the substrate, and said monolayer contains each of the separate chemical components. In general the term co-injecting is used to mean that two or more precursors having at least one different chemical component are present in a chamber such that a film is produced having multiple components. This may be accomplished by injecting or conveying precursors together in either vapor or liquid state (aerosol) into a process chamber, or mixing the precursors in the process chamber. Mixing of the precursors prior to introduction into the process chamber is preferred, but not required.

In another aspect the present invention provides a system for forming multi-component films. In one embodiment, the system generally includes one or more vaporizers, each vaporizer being coupled to a manifold. The manifold is configured to mix the vaporized precursors generated by the vaporizers. The manifold is coupled to an inlet to a process chamber and the mixed precursors are injected into the chamber through the inlet. In one embodiment the inlet is comprised of an injector, such as a showerhead injector. It is possible that the precursors may be mixed in the injector, and not in a manifold.

In yet another aspect of the present invention, systems and methods are provided wherein the process chamber is configured in such a manner as to practice said deposition method on a single substrate. Alternatively, systems and methods are provided wherein the process chamber is configured in such a manner as to practice said deposition methods on a plurality of substrates, typically numbering between 1 and 200 substrates. As an example, it would be possible to process between 1 and 200 substrates when the substrates are silicon wafers with a diameter of 200 mm. More typically, it would be possible to process between 1 and 150 substrates when the substrates are silicon wafers with a diameter of 200 mm. If the substrates are silicon wafer with a diameter of 300 mm, it would be more typical to process between 1 and 100 substrates. Recently, a new version of “mini-batch” reactor has been established in the market whereby a batch of substrates numbering between 1 and 50 would be processed in a single batch. In this case, the substrates would be silicon wafers with diameters of either 200 mm or 300 mm. Finally, some of the new “mini-batch” systems are configured to process between 1 and 25 substrates. Again, in this case, the substrates would be silicon wafers with diameters of either 200 mm or 300 mm.

In a further embodiment, a method of forming a film of a surface of a substrate is provided, characterized in that: two or more precursors, each of the precursors comprising at least one different chemical component are provided, a desired amount of said precursors are converted to a gaseous state by at least one or both of a direct liquid injection system and a bubbler system, said precursors in the gaseous state are conveyed to a process chamber together and form a monolayer on the surface of the substrate, said monolayer containing each of the separate chemical components.

In another aspect, a system for atomic layer deposition (ALD) is provided comprising: at least one direct liquid injection system configured to inject one or more deposition precursors into one or more vaporization chambers, at least one bubble system configured to vaporize one or more deposition precursors; and a process chamber coupled to said direct liquid injection system and said bubblers system, said process chamber being configured to receive the deposition precursors from said direct liquid injection and bubbler systems and being adapted to carry out an ALD process.

In an alternative embodiment, the system is comprised of two separate bubbler systems. In another alternative embodiment, the system is comprised of two separate direct liquid injection systems.

### BRIEF DESCRIPTION OF THE DRAWINGS

Other aspects, embodiments and advantages of the invention will become apparent upon reading of the detailed description of the invention and the appended claims provided below, and upon reference to the drawings in which:

FIG. 1 is a schematic block diagram of a system for fabricating a multi-component film in accordance with one embodiment of the present invention.

FIG. 2 is a schematic block diagram of a system for fabricating a multi-component film in accordance with an alternative embodiment of the present invention.

FIG. 3 is a schematic block diagram of a system for fabricating a multi-component film in accordance with a further embodiment of the present invention.

FIG. 4 is a simplified schematic block diagram illustrating an atomic layer deposition system employing one embodiment of the direct liquid injection system of the present invention.

FIGS. 5A and 5B are simplified partial cross sectional views depicting a batch atomic layer deposition system which may be employed with embodiment of the present invention.

### DETAILED DESCRIPTION OF THE INVENTION

In general, the inventor has discovered a method that provides for mixing precursors such that a mixture of precursors are present in a chamber during a single pulse step in an atomic layer deposition (ALD) process to form a monolayer having multiple chemical compounds on the surface of a substrate. The precursors are comprised of different chemical components, and such components will form the multi-component film. Such a method is a departure from the prior art, where the vaporized precursors are conveyed or pulsed separately into the chamber in the ALD process. A variety of multi-component films may be formed by the present invention, including but not limited to: metal, metal alloy, mixed metal oxides, silicates, nitrides, oxynitrides, and mixtures thereof.

In one aspect, the present invention provides a system and method for reproducibly and substantially uniformly controlling the stoichiometric composition of a multi-component film.

In a series of embodiments, the present invention provides systems and methods for fabricating dielectrics possessing a higher permittivity or dielectric constant than silicon dioxide and capable of preventing current tunneling or leakage. Another aspect of the present invention provides a system and method for fabricating an interface that can ameliorate the surface properties and chemistries of the dielectric and silicon substrate, while minimizing the equivalent oxide thickness.

In another aspect the present invention provides a system for forming multi-component films. In one embodiment, the system generally includes one or more vaporizers, each vaporizer being coupled to a manifold. The manifold is coupled to an inlet to a reaction or deposition chamber, said inlet being comprised of an injector, such as a showerhead injector, and the like.

Each vaporizer holds a single deposition precursor comprising at least one deposition metal. Each vaporizer is connected to a mass flow controller and temperature control unit. The mass flow controller and temperature unit may be selectively controlled to moderate the concentration of deposition precursors present in the process chamber. In one embodiment, each mass flow controller moderates the flow of carrier gas through the system, and, in turn, the carrier gas dilutes and transports the deposition precursor into the manifold or process chamber.

In some series of embodiments, the vaporizer is a bubbler that vaporizes a single deposition precursor comprising at least one deposition metal. A pressurized gas including the carrier gas is bubbled into the deposition precursor. The flow rate of the pressurized gas may be selectively controlled to adjust the concentration of the deposition precursor present in the process chamber. The carrier gas becomes saturated with the vapor of the precursor.

In one embodiment, a manifold facilitates mixing of the deposition precursors prior to delivery into the process chamber. In some embodiments, the manifold contains a T-junction cavity that accommodates and mixes the deposition precursors prior to delivery into the process chamber. The manifold may be heated to facilitate the flow of deposition precursors into the process chamber so as to prevent condensation in the manifold. Alternatively, mixing of the precursors may take place in the process chamber and the manifold may be eliminated.

The deposition precursor is delivered to the process chamber typically via a gas inlet and a monolayer of deposition precursor is chemi and/or physi absorbed on the surface or the substrate. The substrate can be silicon, metal, metal alloy, glass, polymeric, plastic, organic or inorganic work pieces. The gas inlet may take a variety of forms. In one example the gas inlet is comprised of an injector, such as a showerhead injector and the like. Alternatively, the deposition precursor is delivered to the substrate surface by a plurality of injectors.

Generally, the substrate is supported on a wafer support such as an electrostatic or vacuum chuck during deposition when a single wafer chamber is used. In one embodiment, the chuck is capable of cooling or heating the substrate by conduction, convection, radiative or non-radiative processes, or a mixture thereof. Alternatively, the wafer support may be a boat or cassette that supports a plurality of substrates for batch processing. The plurality of substrates typically numbers between 1 and 200 substrates, preferably between 1 and 150 substrates, alternately between 1 and 100 substrates, alternately between 1 and 50 substrates, and optionally between 1 and 25 substrates.

An inlet port switchably provides oxidizing, reducing or nitridating reactants into the process chamber in-situ so as to promote sequential oxidation, reduction or nitridation of the monolayer or substrate surface.

The present invention provides systems and methods for fabricating multi-component films by mixing precursors that contain a mixture of gaseous precursors into the chamber and carrying out the ALD process at relatively low temperatures. In one example of the present invention, the mixture of gaseous precursors contains a metal amide and silicon amide. A monolayer of the mixture of precursors is allowed to form on the substrate surface and the excess mixture is removed by a variety of means. The substrate is then exposed to a nitridating agent such as ammonia, deuterated ammonia, ¹⁵N-ammonia, amines, amides, hydrazines, alkyl hydrazines, nitrogen gas, nitric oxide, nitrous oxide, nitrogen radicals, N-oxides, atomic nitrogen and mixtures thereof. The nitridating agent is allowed to react with the monolayer of precursors. The excess nitridating agent is removed by a variety of means. The substrate is then exposed to an oxidizing agent such as ozone, oxygen, peroxides, water, air, nitrous oxide, nitric oxide, H₂O₂, N-oxides, and mixtures thereof. This forms a single layer of a metal-silicon-nitrogen-oxygen compound on the substrate. This sequence may be repeated as required to deposit the desired thickness.

Of particular advantage, the multi-component film of the invention is formed with a compositional gradient. A compositional gradient may be used to “buffer” the dielectric and the substrate. For example, when the substrate is silicon, a first layer is deposited rich in silicon and lesser amounts of a second deposition metal that makes up the dielectric. Atop the first layer, a second layer comprising predominantly a deposition metal that makes up the dielectric is deposited in addition to substantial lesser amounts of silicon. In some embodiments, additional layers can be added to blend the surface properties and chemistries of the adjacent layers. In various embodiments, each layer can be oxidized, reduced, nitridated, or a combination thereof in-situ. The composition gradient also provides refractive index gradients in the films, which provide unique optical properties of the films.

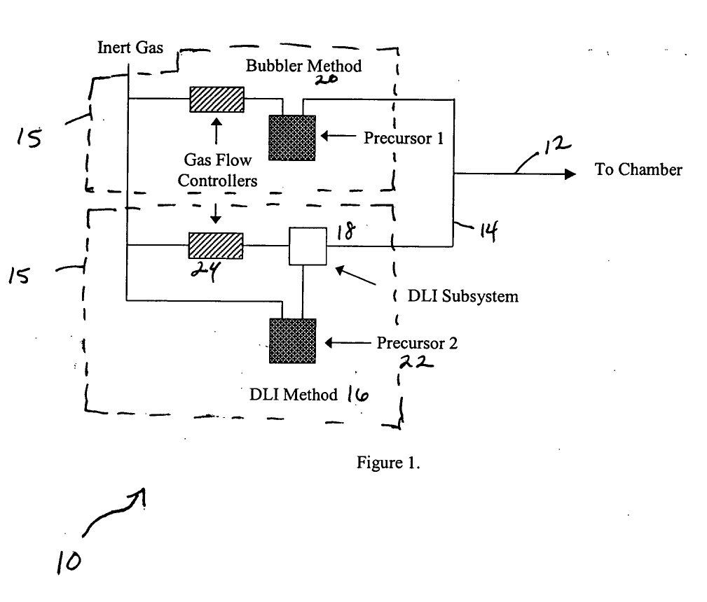

FIG. 1 is a simplified schematic diagram depicting one embodiment of a system for fabricating a multi-component film in accordance with one embodiment of the present invention. Referring to FIG. 1, in general the system 10 comprises a process chamber (not shown) which houses a wafer support for supporting one or more wafers or substrates. A gas inlet 12 is provided for conveying deposition precursors and other gases (for example, reactant gases such as oxidation gases and the like, or dilution gases) into the chamber to form various layers or films on the surface of the substrate. In the illustrative embodiment, a gas manifold 14 interconnects one or more vaporization systems 15 to the process chamber. The illustrative embodiment in FIG. 1 the vaporization system is comprised of at least one DLI system 16 and one Bubbler system 20, however, any number of vaporization systems may be employed. Each DLI system 16 comprises one or more reservoirs 22 for holding a deposition precursor or a mixture of deposition precursors, and one or more vaporizer elements 18 through which a carrier gas is flowed to assist in vaporizing the contents in reservoirs 22. The flow of carrier gas into the DLI vaporizers 18 may be adjusted using a mass flow controller 24 to control the rate and concentration of the deposition precursors vaporized.

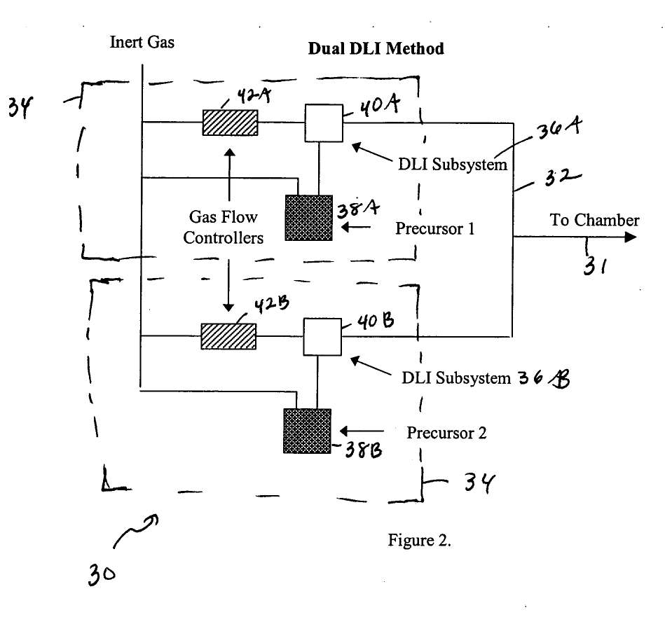

FIG. 2 is a simplified schematic diagram depicting another embodiment of a system for fabricating a multi-component film. Referring to FIG. 2, in general the system 30 comprises a process chamber (not shown) which houses wafer support for supporting a wafer or substrate. A gas inlet 31 is provided for conveying deposition precursors and other gases (for example, reactant gases such as oxidation gases and the like, or dilution gases) into the chamber to form various layers or films on the surface of the substrate. In the illustrative embodiment, a gas manifold 32 interconnects one or more vaporization systems 34 to the process chamber. The illustrative embodiment in FIG. 2 shows two DLI systems 36A and 36B however, any number of vaporization means may be employed. Each DLI system 36A and 36B comprises a reservoir 38A and 38B for holding a deposition precursor or a mixture of deposition precursors, and vaporizer elements 40A and 40B through which a carrier gas is flowed to assist in vaporizing the contents in reservoirs 38A and 38B. The flow of carrier gas into the vaporizers 40A and 40B may be adjusted using respective mass flow controllers 42A and 42B to control the rate and concentration of the deposition precursors vaporized.

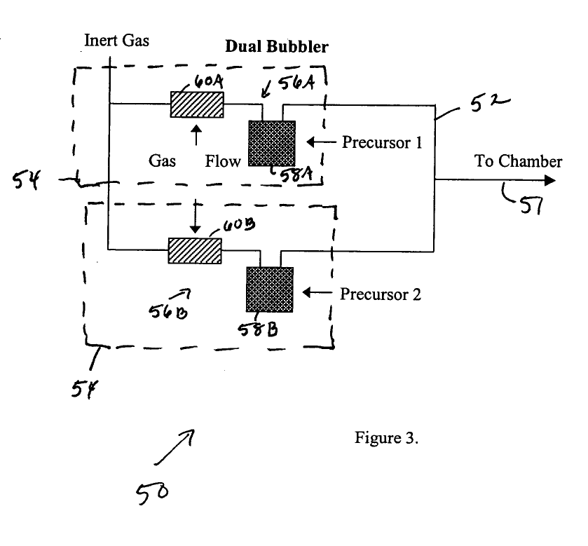

FIG. 3 is a simplified schematic diagram depicting one embodiment of a system for fabricating a multi-component film in accordance with one embodiment of the present invention. Referring to FIG. 3, in general the system 50 comprises a process chamber (not shown) which houses wafer support for supporting a wafer or substrate. A gas inlet 51 is provided for conveying deposition precursors and other gases (for example, reactant gases such as oxidation gases and the like, or dilution gases) into the chamber to form various layers or films on the surface of the substrate. In the illustrative embodiment, a gas manifold 52 interconnects one or more vaporization systems 54 to the process chamber. The illustrative embodiment in FIG. 3 shows two Bubbler vaporizer systems 56A and 56B however, any number of vaporization means may be employed. Each Bubbler vaporizer system 56A and 56B comprises a reservoir 58A and 58B for holding a deposition precursor or a mixture of deposition precursors, through which a carrier gas is flowed to assist in vaporizing the contents in reservoirs 58A and 58B. The flow of carrier gas into the Bubbler vaporizer systems 56A and 56B may be adjusted using respective mass flow controllers 60A and 60B to control the rate and concentration of the deposition precursors vaporized.

In one embodiment of the present invention, deposition precursors comprising at least one deposition metal are used having the formula:
M(L)ₓ
where M is a metal selected from the group consisting of Ti, Zr, Hf, Ta, W, Mo, Ni, Si, Cr, Y, La, C, Nb, Zn, Fe, Cu, Al, Sn, Ce, Pr, Sm, Eu, Tb, Dy, Ho, Er, Tm, Yb, Lu, Ga, In, Ru, Mn, Sr, Ba, Ca, V, Co, Os, Rh, Ir, Pd, Pt, Bi, Sn, Pb, Tl, Ge and mixtures thereof; where L is a ligand selected from the group consisting of amine, amides, alkoxides, halogens, hydrides, alkyls, azides, nitrates, nitrites, cyclopentadienyls, carbonyl, carboxylates, diketonates, acetamidinates, ketoimides, diimides, alkenes, alkynes, substituted analogs thereof, and combinations thereof; and where x is an integer less than or equal to the valence number for M.

It is beneficial to select the ligands (L) to be the same in each of the deposition precursors to avoid ligand exchange from taking place when each of the precursors is mixed in vaporous form. Ligand exchange can lead to the formation of particulates that can adversely affect the quality of the deposited film. Ligands that do not undergo ligand exchange in vaporous form are also suitable.

In one preferred embodiment two deposition precursors are selected, a first deposition precursor where M is hafnium and a second deposition precursor where M is silicon. Both the first and second deposition precursor have the same ligands (L) to avoid ligand exchange from taking place when the first and second deposition precursor are mixed. Suitable ligands include, but are not limited to, dimethylamine, diethylamine, diethyl methyl amine or tert-butoxide.

The hafnium source may comprise any one or combination of hafnium dialkyl amides, hafnium alkoxides, hafnium dieketonates, hafnium chloride (HfCl₄), tetrakis(ethylmethylamino) hafnium (TEMA-Hf), and the like. The silicon source may comprise any one or combination of aminosilane, silicon alkoxides, silicon dialkyl amides, silane, silicon chlorides, tetramethyldisiloxane (TMDSO), tetrakis(ethylmethylamino) silicon (TEMA-Si), and the like. In one preferred embodiment, the liquid precursors 124, 126, are comprised of TEMA-Hf and TEMA-Si, respectively.

Deposition precursors are vaporized by direct liquid injection, by a bubbler system, or by a combination of both. Each vaporizer holds a single deposition precursor. In some embodiments, each system includes one or more vaporizers connected to a mass flow controller and a heating mechanism. As described above according to one embodiment of the present invention, a compositional gradient of one or more of the chemical components in the deposited film is provided. In one example, selective control of the composition is achieved by controlling the amount of precursor that is vaporized. The amount of precursor vaporized is generally controlled by adjusting the gas flow controller and/or the temperature unit that heats the vaporizer in order to vaporize a desired concentration of the selected precursor(s). Additionally or alternatively, a dilution gas may be conveyed into the injector or manifold (not shown) and the flow rate of the dilution gas may be selectively controlled to dilute the amount of deposition precursor conveyed to the chamber.

The vaporizer may be comprised of a bubbler that vaporizes the deposition precursor comprising at least one deposition metal. When the vaporizer is a bubbler, pressurized gas such as a carrier gas is bubbled into the deposition precursor reservoir. Useful carrier gases include nitrogen, argon, or helium gas. The pressurized gas dilutes and carries the deposition precursors into their respective deposition precursor conduits, and facilitates mixing of the deposition precursors. Optionally, to provide a compositional gradient in the film the concentration of one or more of the deposition precursors can be operablly controlled by varying the temperature of the bubbler to selectively increase or decrease the amount of deposition precursor vaporized. Temperature control can be conducted independently or in tandem with control of the mass flow controller and/or with the flow rate of the carrier gas. Thus, each of the various control mechanisms can be used independently, or in a variety of combinations.

In other embodiments, due to the nature of the deposition precursors, the deposition precursors can be volatilized in reservoir by photolysis or enzymatic or chemical catalysis.

In another embodiment, the precursor reservoir may contain a mixture of precursor chemicals. The mixture generally contains at least one metal compound. The ligands of the precursor chemicals are chosen with the same ligands so that there is no change in the chemical nature of the mixture upon ligand exchange. Alternatively, the ligands are chosen such that the chemicals are stable relative to each other and no ligand exchange occurs. This mixture can then be delivered as a “mixed liquid” using Direct Liquid Injection (DLI) system and vaporized in a suitable vaporizer apparatus and delivered to the conduits as a gaseous mixture of the precursors. It is clear that this embodiment allows the formation of materials with a wide range of multiple components without having to duplicate the individual hardware required to deliver each unique chemical precursor. Examples of materials that may be deposited using the present invention include, but are not limited to, HfSiOₓ, HfSiON, HfSiN, TiAlN, TiSiN, TaAlN, TaSiN, HfTiOₓ, Ta—Ru alloys, quaternary metal oxides with the formula AₓB_{y}C_{z}O, quaternary metal nitrides with the formula AₓB_{y}C_{z}N, and the like.

In another embodiment, the precursor reservoir may contain a mixture of precursor chemicals. The mixture generally contains at least one metal compound. The ligands of the precursor chemicals are chosen with the same ligands so that there is no change in the chemical nature of the mixture upon ligand exchange. Alternatively, the ligands are chosen such that the chemicals are stable relative to each other and no ligand exchange occurs. This mixture can then be delivered as an “aerosol” using well-known means and vaporized in a suitable vaporizer apparatus and delivered to the conduits as a gaseous mixture of the precursors. It is clear that this embodiment allows the formation of materials with a wide range of multiple components without having to duplicate the individual hardware required to deliver each unique chemical precursor. Examples of materials that may be deposited using the present invention include, but are not limited to, HfSiOₓ, HfSiON, HfSiN, TiAlN, TiSiN, TaAlN, TaSiN, HfTiOₓ, Ta—Ru alloys, quaternary metal oxides with the formula AₓB_{y}C_{z}N, quaternary metal nitrides with the formula AₓB_{y}C_{z}N, and the like.

Referring again to FIGS. 1-3, after the deposition precursors are vaporized, they are conveyed into a manifold through deposition precursor conduits to a chamber. The deposition precursor conduits can be of any shape, size, and length. The conduits can be fabricated from metal, plastics, polymers, or alloys. Typically, the conduits are made of the same material as the manifold. Similar to the manifold, the conduits can be insulated or heated to facilitate vaporization. Optionally, the conduits and the manifold contain a sampling region for measuring the vapor concentration and composition spectroscopically or spectrometrically.

Mixing of the precursors can be facilitated by gravity or pressurized gas. Mixing can also be achieved by physical means such as a plunger to forcibly inject the precursors into the manifold through the conduits, where the precursors are permitted to mix into a homogeneous deposition mixture. In some embodiments, the conduits converge and terminate at T-junction in the manifold, where the precursors mix prior to delivery into the process chamber.

Alternatively, the conducts can converge and convey the respective precursors directly into a mixing region or cavity near or inlet to the chamber. In some embodiments, a filter can be inserted or attached to the manifold to remove unwanted or isolate particular impurities and gases.

Optionally, referring back to the manifold and conduits, a heating or cooling element internally embedded or externally located can be used to regulate mixing and minimize particulate and impurity formation in the films.

The manifold may take many forms suitable for mixing of the precursors prior to conveying the precursors to the chamber. The manifold may be a single conduit coupled to the vaporizers via a junction, such as T-junction. The manifold may include a cavity or reservoir to provide some residence time for the precursors to mix. In an alternative embodiment the manifold may be eliminated altogether, and the deposition precursors are conveyed directly to the gas inlet and mixed in the gas inlet (such as when the gas inlet is comprised of an injector) as they are conveyed into the chamber.

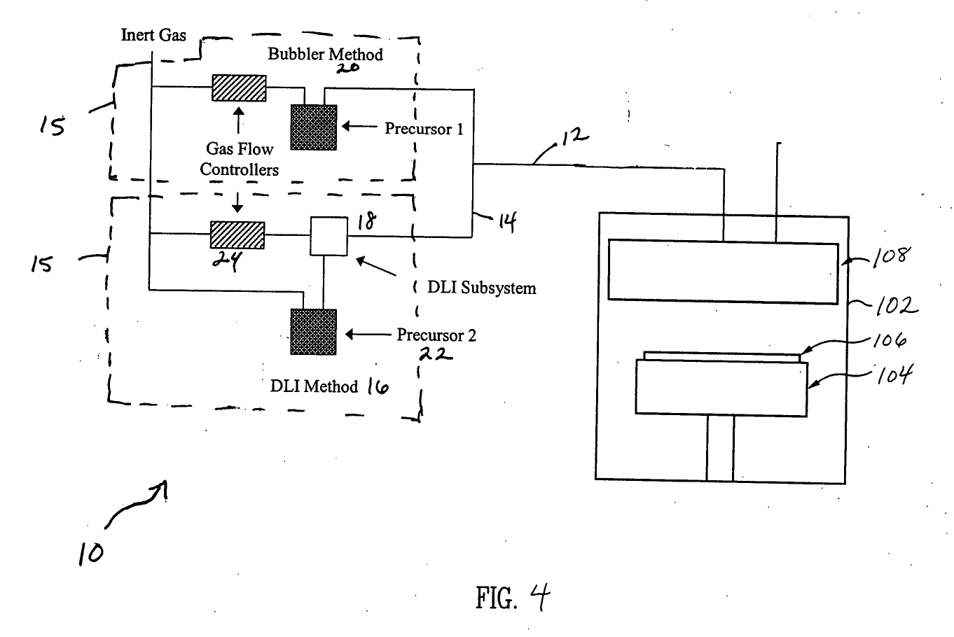

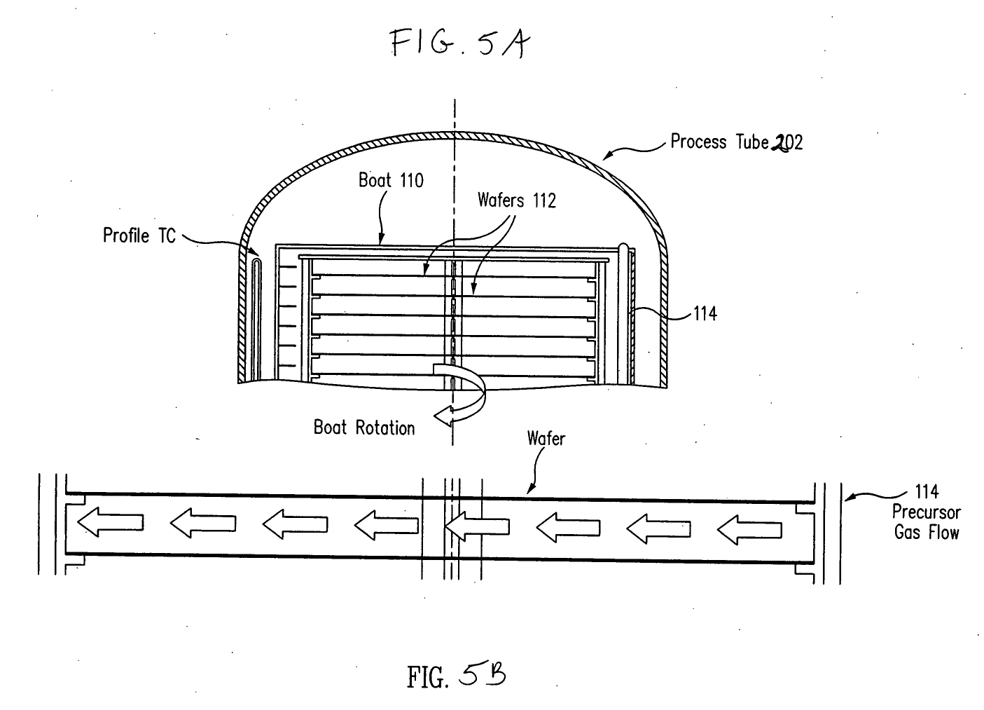

Referring to FIGS. 4, 5A and 5B, once the precursors have been vaporized in system 10, they are conveyed to a chamber via one or more gases inlets. The gas inlet may take a variety of forms for delivery of gases to the chamber. In one embodiment shown in FIG. 4, the chamber is comprised of a single wafer chamber. As illustrated in FIG. 4 the atomic layer deposition system generally comprises a process chamber 102 which houses a wafer support 104 for supporting a wafer or substrate 106. Gas manifold 14 interconnects the one or more vaporization systems 15 to the process chamber 102 via gas inlet 12. In some embodiments, the gas inlet 12 conveys vaporized gases to an injector 108, such as a showerhead injector or a linear injector. It is also within the scope of the invention to incorporate a showerhead that utilizes a plurality of injectors adjustable in the process chamber to provide desirable films. While one specific embodiment is shown in FIG. 4, alternative arrangements are within the scope of the invention. For example, the vaporization systems 30 and 50 illustrated in FIGS. 2 and 3, respectively, may be employed with the process chamber 102.

In some embodiments the present invention may be employed with a batch-processing chamber, or with a mini-batch chamber, as generally shown in FIGS. 5A and 5B. In a batch or mini-batch chamber 202, a boat 110 houses a plurality of wafers or substrates 112. A plurality of gas inlets 114 are employed and the gases may be conveyed over each substrate in a parallel or cross-flow manner as illustrated in FIG. 5B. Examples of a mini-batch chamber are described in PCT patent application serial no. PCT/US03/21575 entitled Thermal Processing System and Configurable Vertical Chamber, the disclosure of which is incorporated by reference herein. Alternative batch and mini-batch chamber configurations, for example chambers which do not provide cross-flow, may also be practiced with the present invention.

A layer of the deposition mixture, comprising the precursors, is deposited on the substrate. Suitable substrates include metal, metal alloy, glass, polymeric, plastic, organic or inorganic work pieces. Depending on the mode of deposition, a monolayer or monolayers of the deposition mixture will form on the substrate. The preferred method for deposition is Atomic Layer Deposition. However, the systems and methods of the present invention may be employed with other deposition techniques.

Referring again to FIGS. 1-3, following deposition of the deposition mixture, excess mixture is purged out of the system through an exhaust port connected to a vacuum pump that controls the system pressure, gas flow and insures rapid purging of the process chamber (not shown) after each deposition process. The wafer support (not shown) is used to support and heat the substrate during a deposition or annealing step. The wafer support typically contains heating and cooling elements formed therein. An external heater (not shown) may also be used to control the temperature of the process chamber. Preferably, the wafer support is a vacuum or electrostatic chuck.

The process chamber (not shown) has an inlet switchably and sequentially capable of supplying other gases used in the process or in cleaning of the chamber. Reactant gases may be conveyed into the chamber via the inlet. Suitable reactant gases include oxidizing gas, reducing gas, nitridating gas, or mixtures thereof. Other gases that may be conveyed through the inlet include carrier or inert gas, or mixtures thereof.

In one preferred embodiment, vaporized deposition precursors are mixed in a manifold prior to introduction into the reaction chamber in order to provide a more uniform film and to permit maximum control of the composition of the film. However, it is possible to separately convey each vaporized precursor to a gas inlet, such as an injector and the like, which mixes the gases as they are injected into the chamber, thus eliminating the need for a separate manifold. A variety of mechanical embodiments are suitable in light of the teaching of the present invention, and the present invention is not limited to any one mechanical configuration. The teaching of the present invention provides that at least some mixing of the various different precursors takes place such that a mixture of precursors having different chemical components is present in the process chamber to form a film having multiple components in one monolayer.

A reactant gas may be introduced into the process chamber through the inlet, to treat and/or react with the monolayer comprising the deposition mixture on the surface of the substrate. Reactant gases can be supplied sequentially or simultaneously mixed with the deposition precursors in the gas inlet or directly into the process chamber.

A variety of reactant gases may be used depending on the application. If the reactant gas is an oxidizing gas, the monolayer is oxidized. If the reactant gas is a reducing gas, the monolayer is reduced. Similarly, if the reactant gas is a nitridating gas, the monolayer is nitridated. Suitable oxidizing gases include ozone, oxygen, singlet oxygen, triplet oxygen, water, peroxides, air, nitrous oxide, nitric oxide, H₂O₂, and mixtures thereof. Suitable reducing gases include hydrogen. Suitable nitridating gases include ammonia, deuterated ammonia, ¹⁵N-ammonia, hydrazine, alkyl hydrazines, nitrogen dioxide, nitrous oxide, nitrogen radical, nitric oxide, N-oxides, amides, amines, and mixtures thereof. In another embodiment, after the deposition precursor has been deposited on the substrate, the substrate can be transferred in vacuum to a second processing unit capable of nitridating, oxidizing, reducing, or annealing the monolayer on the substrate.

In one example, to form a multi-component film comprising HfSiN by ALD, hafnium and silicon deposition precursors (for example: TEMA-Hf and TEMA-Si, respectively) are vaporized, mixed and conveyed (also referred to as “pulsed”) to the process chamber together, along with a nitrogen containing source such as NH₃ to form HfSiN. The process may be carried out where the Hf and Si deposition precursors are mixed together and pulsed into the process chamber, then purged. The nitrogen source gas (such as NH₃) is pulsed and purged. These steps form one ALD cycle to form the HfSiN film. In another embodiment, a further pulse and purge step is performed with an oxidizing agent, such as ozone, in one ALD cycle to form an HfSiON film.

In one example the ALD process is carried out at a process temperature in the range of approximately 25 to 800° C., more usually in the range of approximately 50 to 600° C., and most usually in the range of approximately 100 to 500° C. The pressure in the process chamber is in the range of approximately 0.001 mTorr to 600 Torr, more usually in the range of approximately 0.01 mTorr to 100 Torr, and most usually in the range of approximately 0.1 mTorr to 10 Torr. This pressure range covers both the pulse and purge steps. The total inert gas flow rate in the process chamber, including the carrier gas in the bubblers when used, is generally in the range of approximately 0 to 20,000 sccm, and more usually in the range of approximately 0 to 5,000 sccm.

Optionally, after the deposition precursor has been deposited on the substrate, the substrate can be transferred in vacuo to a second processing unit capable of nitridating, oxidizing, reducing, or annealing the monolayer on the substrate.

Suitable sources of hafnium include hafnium dialkyl amides, hafnium alkoxides, hafnium diketonates or hafnium halides. Suitable sources of silicon include silicon halides, silicon dialkyl amides or amines, silicon alkoxides, silanes, disilanes, siloxanes, aminodisilane, and disilicon halides. Typically, sources of hafnium and silicon are selected having common ligands to prevent complications arising from ligand exchange. Covalently bridged mixed metals, as disclosed in PCT patent application serial number PCT/US03/22236 entitled Molecular Layer Deposition Of Thin Films With Mixed Components, incorporated herein by reference, as well as non-covalently bonded mixed metals may be used as precursors for deposition. Types of non-covalent bonds include hydrogen bonds, dative bonds, metal-metal bonds, metal-π, metal-π*, π-π bonds, sigma-sigma bonds, ionic bonds, Van Der Waals interactions, hydrophobic/hydrophilic interactions, polar bonds or dipole moment interactions. Sources of inert gases include carrier gases such as argon, nitrogen, inert gases, or a mixture thereof.

Optionally, if desired, instead of relying on heat to form and anneal the nitride layer, nitridation can be facilitated by light or any combination of light, heat and chemical initiators. For example, in certain embodiments, direct plasma, remote plasma, downstream plasma, ultraviolet photon energy, or a combination thereof, can be used to facilitate nitridation. Activation energy sources include plasma, light, laser, radical, and microwave energy sources, and mixtures thereof.

As previously mentioned in a separate embodiment, suitable nitrogen sources include ammonia, deuterated ammonia, ¹⁵N enriched ammonia, amines, amides, nitrogen gas, hydrazines, alkyl hydrazines, nitrous oxide, nitric oxide, nitrogen radicals, N-oxides, or a mixture thereof.

In yet another illustrative example, a first precursor vaporizer is provided having a first precursor comprising Hf (e.g. TEMA-HF). A second precursor vaporizer having a second precursor comprising Si (e.g. TEMA-Si) is also provided. A “batch” of substrates or wafers (e.g. 50 substrates) are positioned on the substrate holder in the process chamber. In this example, the process chamber is part of a vertical furnace system well known in the art. The process chamber is evacuated, and the substrates heated to a predetermined processing temperature. As noted above the process temperature is preferably from approximately 50 to 800° C., and more preferably from approximately 100 to 500° C. For this example, the desired temperature was 275° C. The first and second precursors are vaporized by bubbling a gas through the reservoirs to form first and second vaporized precursors, mixed, and flowed to the process chamber. The mixed first and second vaporized precursors are directed onto the substrates through a suitable gas inlet such as an injector and form a monolayer consisting of the chemical elements of both precursors (e.g. Hf-compounds and Si-compounds). Excess amounts of the mixed first and second precursors are removed by a suitable means and a pulse of ozone is allowed to flow into the process chamber to react with the monolayer of the mixed first and second precursors and form a homogeneous layer of hafnium silicate (e.g. HfₓSi₁₋ₓO₂). Note that the present invention specifically does not result in a “mixture” of HfO₂and SiO₂ compounds in the layer. This sequence is repeated until the desired thickness is achieved. In this manner, the “co-injection” method has been successfully applied simultaneously to a plurality of substrates

In accordance with the present invention, numerous layers of having different film thickness and compositions can be deposited. While specific examples describing the formation of SiO₂, HfO₂, HfSiOₓ, HfN, SiN, SiON and HfSiON are shown herein, it will be apparent to those of ordinary skill in the art that the inventive methods and ALD systems may be employed to generate any thickness, composition, or types of thin films comprising metal, metal alloys, mixed metal oxides, silicates, nitrides, oxynitrides, or combinations thereof.

The foregoing descriptions of specific embodiments of the invention have been presented for the purpose of illustration and description. They are not intended to be exhaustive or to limit the invention to the precise forms disclosed, and obviously many modifications, embodiments, and variations are possible in lights of the above teaching. It is intended that the scope of the invention be defined by the Claims appended hereto and their equivalents.

What is claimed:

1. A method for forming a film on a surface of a substrate comprising the steps of:
vaporizing two or more precursors by any one or combination of direct liquid injection and bubbler vaporization, each of the precursors containing at least one metal or metalloid component;
conveying the two or more precursors into a process chamber wherein the precursors are present together in the process chamber;
forming a monolayer on the surface of the substrate, said monolayer containing each of the metal or metalloid components;
removing excess mixture of said precursors from said process chamber;
conveying a first reactant to said process chamber and allowing said first reactant to react with the monolayer of the mixed precursors to form a metal-containing material;
removing excess amounts of the first reactant from the process chamber;
conveying an second reactant to said process chamber and allowing said second reactant to react with the monolayer of the metal-containing material to form a metal-(first reactant)-(second reactant) material, and
repeating the sequence until the desired thickness of the film is reached.

2. The method of claim 1 wherein, said substrate surface is selected from the group of: semiconductor materials, compound semiconductor materials, silicon, plastics, polymers, metals, alloys, organics, inorganics, and mixtures thereof.

3. The method of claim 1 wherein, the first precursor and the second precursor each have the formula:
M(L)ₓ
where M is a metal selected from the group of: Ti, Zr, Hf, Ta, W, Mo, Ni, Si, Cr, Y, La, C, Nb, Zn, Fe, Cu, Al, Sn, Ce, Pr, Sm, Eu, Tb, Dy, Ho, Er, Tm, Yb, Lu, Ga, In, Ru, Mn, Sr, Ba, Ca, V, Co, Os, Rh, Ir, Pd, Pt, Bi, Sn, Pb, Ti, Ge and mixtures thereof;
where L is a ligand selected from the group consisting of amine, amides, alkoxides, halogens, hydrides, alkyls, azides, nitrates, nitrites, cyclopentadienyls, carbonyl, carboxylates, diketonates, acetamidinates, ketoimides, diimides, alkenes, alkynes, substituted analogs thereof, and combinations thereof; and
where x is an integer less than or equal to the valence number for M.

4. The method of claim 1, wherein said first reactant or second reactant is selected from the group of: ammonia, deuterated ammonia, ¹⁵N-ammonia, amines, amides, hydrazines, alkyl hydrazines, nitrogen gas, nitric oxide, nitrous oxide, nitrogen radicals, N-oxides, and mixtures thereof.

5. The method of claim 1, wherein said first reactant or second reactant is selected from the group consisting of: ozone, oxygen, singlet oxygen, triplet oxygen, atomic oxygen, water, peroxides, air, nitrous oxide, nitric oxide, H₂O₂, and mixtures thereof.

6. The method of claim 1, wherein said step of vaporizing in said Direct liquid injection system further comprises conveying said precursors in the liquid state into a vaporizer chamber wherein the precursors are caused to evaporate into the gaseous state.

7. The method of claim 1, wherein said step of vaporizing in said bubbler further comprises: bubbling a carrier gas though a container filled with the liquid state of said precursor to saturate the carrier gas with vapor of said precursor; and conveying said saturated carrier gas to the process chamber.

8. The method of claim 1 wherein said precursors are a single metal-containing chemical.

9. The method of claim 1 wherein said precursors are a mixture of metal-containing chemicals.

10. The method of claim 1 wherein said method is carried out at a temperature in the range of approximately 20 to 800 C.

11. The method of claim 1 wherein said method is carried out wherein said process chamber is at a pressure in the range of approximately 0.001 mTorr to 600 Torr.

12. The method of claim 1 wherein said method is carried out wherein the total gas flow rate to the process chamber comprising the conveying of the precursors, nitridating reactant, oxidizing reactant, and additional purge gases during any single step is in the range of approximately 0 to 20,000 sccm.

13. The method of claim 1 wherein said process chamber is configured in such a manner as to practice said film forming method on a single substrate.

14. The method of claim 1 wherein said process chamber is configured in such a manner as to practice said film forming method on a plurality of substrates.

15. The system of claim 14, wherein the plurality of substrates numbers between 1 and 200.

16. A method of forming a film on a surface of a substrate, characterized in that: two or more precursors, each of the precursors containing at least one different chemical component, a desired amount of said precursors being controlled while the precursor is in the liquid state, said desired amount of said precursors being converted to a gaseous state by any one or combination of direct liquid injection or bubbler systems, said gaseous state of the precursors are conveyed to a process chamber together and form a monolayer on the surface of the substrate, said monolayer containing each of the separate chemical components.

17. A system for atomic layer deposition (ALD), comprising:
at least one direct liquid injection system configured to inject one or more deposition precursors into one or more vaporization chambers,
at least one bubbler system configured to vaporize one or more deposition precursors; and
a process chamber coupled to said direct liquid injection system and said bubbler system, said process chamber being configured to receive the deposition precursors from said direct liquid injection and bubbler systems and being adapted to carry out an ALD process.

18. A system for atomic layer deposition (ALD), comprising:
a first bubbler system configured to vaporize one or more deposition precursors;
a second bubbler system configured to vaporize one or more deposition precursors; and
a process chamber coupled to said first and second bubbler systems, said process chamber being configured to receive the deposition precursors from said first and second bubbler systems and being adapted to carry out an ALD process.
